(19) United States
(12) Patent Application Publication
(10) Pub. No.: US 2015/0228820 A1
(43) Pub. Date: Aug. 13, 2015

(54) FRONT CONTACT FOR A SOLAR CELL, AND METHOD OF MAKING SAME

(71) Applicant: TSMC SOLAR LTD., Taichung City (TW)

(72) Inventor: Shih-Wei CHEN, Kaohsiung City (TW)

(73) Assignee: TSMC SOLAR LTD., Taichung City (TW)

(21) Appl. No.: 14/174,893

(22) Filed: Feb. 7, 2014

(51) Int. Cl. H01L 31/0224; H01L 31/18

(52) U.S. Cl. CPC H01L 31/022433; H01L 31/18

(57) ABSTRACT

A solar cell has a back contact layer over a substrate; an absorber layer over the back contact layer, having a scribe line extending through the back contact layer; and a front contact layer over the absorber layer. The front contact layer has a first end and a second end opposite the first end. The scribe line is closer to the second end than to the first end, and the front contact layer has a thickness above the scribe line that is greater than the thickness of the front contact layer at the first end.

### PRIORITY CLAIM AND CROSS-REFERENCE

None.

### BACKGROUND

This disclosure related to fabrication of thin film photovoltaic cells.

Solar cells are electrical devices for generation of electrical current from sunlight by the photovoltaic (PV) effect. Thin film solar cells have one or more layers of thin films of PV materials deposited on a substrate. The film thickness of the PV materials can be on the order of nanometers or micrometers.

Examples of thin film PV materials used as absorber layers in solar cells include copper indium gallium selenide (CIGS) and cadmium telluride. Absorber layers absorb light for conversion into electrical current. Solar cells also include front and back contact layers to assist in light trapping and photo-current extraction and to provide electrical contacts for the solar cell. The front contact typically comprises a transparent conductive oxide (TCO) layer. The TCO layer transmits light through to the absorber layer and conducts current in the plane of the TCO layer. In some systems, a plurality of solar cells are arranged adjacent to each other, with the front contact of each solar cell conducting current to the next adjacent solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross sectional view of a solar panel, in accordance with some embodiments.

FIG. 2 is an enlarged detail of a solar cell in the solar panel of FIG. 1, in accordance with some embodiments.

FIG. 3 is an isometric view of the transparent conductive oxide (TCO) layer of FIG. 2, in accordance with some embodiments.

FIGS. 4A-4D are cross-sectional views showing four steps in the fabrication of the solar panel of FIG. 1, in accordance with some embodiments.

FIG. 5A is a diagram of a sputtering chamber for depositing the TCO layer of FIG. 1, in accordance with some embodiments.

FIG. 5B shows the mask of FIG. 5A, in accordance with some embodiments.

FIG. 6 shows an alternative configuration of a sputtering chamber, having a variable aperture for forming the TCO layer, in accordance with some embodiments.

FIG. 7 is a flow chart of a method of making a solar cell, in accordance with some embodiments.

FIGS. 8A-8C are flow charts of three variations of step 712 of FIG. 7, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a thin-film photovoltaic solar cell, it is desirable for the front contact to have high optical transmittance so the absorber can absorb more photons, and also to have high conductivity, to reduce series resistance. Although reducing the dopant concentration provides higher transmittance to allow more light pass through the TCO layer, lower dopant concentration results in lower carrier concentration, which reduces output current due to higher resistance. The converse is also true. Increasing doping improves carrier concentration, for better series resistance, but at the same time reduces transmittance, so that fewer photons are captured in the absorber layer.

Some embodiments described herein provide a textured TCO layer to enhance photocurrent by creating a thickness gradient along a specific direction, from an end opposite the interconnect structure to at least the P2 scribe line of the interconnect structure. This design can reduce carrier recombination and provide additional higher TCO transmittance.

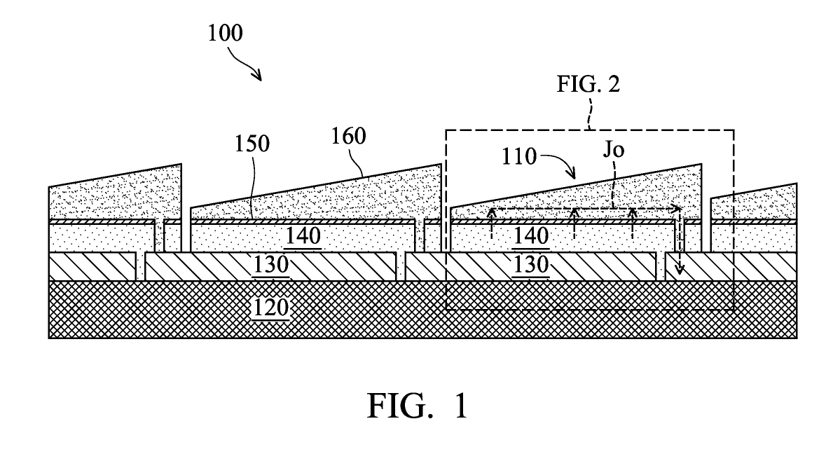

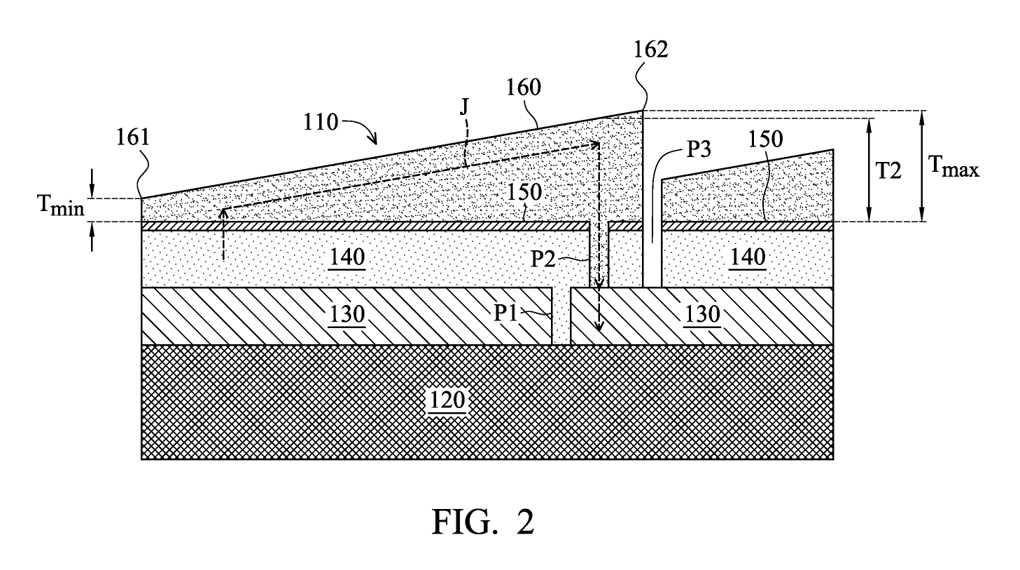

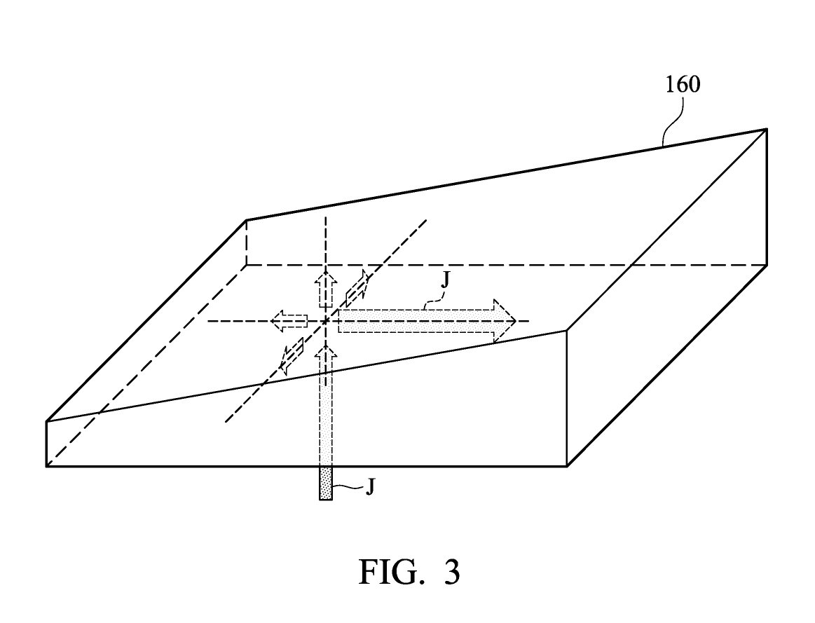

FIG. 1 shows a solar panel, in accordance with some embodiments. FIGS. 2 and 3 show a detail of the TCO layer of one of the solar cells in FIG. 1.

FIG. 1 is a cross sectional view of a solar panel 100 according to some embodiments. The solar panel 100 includes a plurality of solar cells 110 connected in series. The solar panel 100 includes a solar cell substrate 120, a back contact layer 130, a an absorber layer 140, a buffer layer 150 and a front contact layer 160.

Substrate 120 can include any suitable substrate material, such as glass. In some embodiments, substrate 120 includes a glass substrate, such as soda lime glass, or a flexible metal foil or polymer (e.g., a polyimide, polyethylene terephthalate (PET), polyethylene naphthalene (PEN)). Other embodiments include still other substrate materials.

Back contact layer 130 includes any suitable back contact material, such as metal. In some embodiments, back contact layer 130 can include molybdenum (Mo), platinum (Pt), gold (Au), silver (Ag), nickel (Ni), or copper (Cu). Other embodiments include still other back contact materials. In some embodiments, the back contact layer 130 is from about 50 nm to about 2 μm thick.

In some embodiments, absorber layer 140 includes any suitable absorber material, such as a p-type semiconductor. In some embodiments, the absorber layer 140 can include a chalcopyrite-based material comprising, for example, Cu(In,Ga)Se₂ (CIGS), cadmium telluride (CdTe), CulnSe₂ (CIS), CuGaSe₂ (CGS), Cu(In,Ga)Se₂ (CIGS), Cu(In,Ga)(Se,S)₂ (CIGSS), CdTe or amorphous silicon. Other embodiments include still other absorber materials. In some embodiments, the absorber layer 140 is from about 0.3 μm to about 3 μm thick.

Buffer layer 150 includes any suitable buffer material, such as n-type semiconductors. In some embodiments, buffer layer 150 can include cadmium sulphide (CdS), zinc sulphide (ZnS), zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer 150 is from about 1 nm to about 500 nm thick.

In some embodiments, front contact layer 160 includes an annealed transparent conductive oxide (TCO) layer. The terms “front contact” and “TCO layer” are used interchangeably herein; the former term referring to the function of the layer 160, and the latter term referring to its composition. In some embodiments, the charge carrier density of the TCO layer 160 can be from about 1×10¹⁷ cm⁻³ to about 1×10²¹ cm⁻³. The TCO material for the annealed TCO layer can include suitable front contact materials, such as metal oxides and metal oxide precursors. In some embodiments, the TCO material can include AZO, GZO, AGZO, BZO or the like) AZO: alumina doped ZnO; GZO: gallium doped ZnO; AGZO: alumina and gallium co-doped ZnO; BZO: boron doped ZnO. In other embodiments, the TCO material can be cadmium oxide (CdO), indium oxide (In₂O₃), tin dioxide (SnO₂), tantalum pentoxide (Ta₂O₅), gallium indium oxide (GaInO₃), (CdSb₂O₃), or indium oxide (ITO). The TCO material can also be doped with a suitable dopant.

In some embodiments, ZnO can be doped with any of aluminum (Al), gallium (Ga), boron (B), indium (In), yttrium (Y), scandium (Sc), fluorine (F), vanadium (V), silicon (Si), germanium (Ge), titanium (Ti), zirconium (Zr), hafnium (Hf), magnesium (Mg), arsenic (As), or hydrogen (H). In other embodiments, SnO₂ can be doped with antimony (Sb), F, As, niobium (Nb), or tantalum (Ta). In other embodiments, In₂O₃ can be doped with tin (Sn), Mo, Ta, tungsten (W), Zr, F, Ge, Nb, Hf, or Mg. In other embodiments, CdO can be doped with In or Sn. In other embodiments, GaInO₃ can be doped with Sn or Ge. In other embodiments, CdSb₂O₃ can be doped with Y. In other embodiments, ITO can be doped with Sn. Other embodiments include still other TCO materials and corresponding dopants.

Solar cell 100 also includes an interconnect structure that includes three scribe lines, referred to as P1, P2, and P3. The P1 scribe line extends through the back contact layer 130 and is filled with the absorber layer material. The P2 scribe line extends through the buffer layer 150 and the absorber layer 140, and contacts the back contact 130 of the next adjacent solar cell. The P2 scribe line is filled with the front contact layer material forming the series connection between adjacent cells. The P3 scribe line extends through the front contact layer 160, buffer layer 150 and absorber layer 140.

In some embodiments, the front contact layer 160 has a first end 161 and a second end 162 opposite the first end 161, wherein the P2 scribe line is closer to the second end 162 than to the first end 161, and the front contact layer 160 has a thickness T2 above the P2 scribe line that is greater than the thickness Tmin of the front contact layer at the first end 161.

When light impinges on the solar cell 110 of FIGS. 1 and 2, electron-hole pairs are excited by incident photons. At the same time, electrons will move toward the P2 channel. The electron current J flows vertically in one direction due to the p-n junction (at the interface between the absorber layer 140 and buffer layer 150) where the electric field is downward.

Within the TCO layer 160, the current J in the horizontal direction tends to flow towards the P2 channel, from left to right in FIGS. 1 and 2. FIG. 1 shows a current path J₀, which the charge carriers would follow in a TCO layer (not shown) having a uniform thickness. Because the TCO layer 160 picks up additional charge carriers proceeding from left to right, the current density increases from left to right. Nevertheless, the current distribution depends on the localized resistance distribution. For a uniform TCO thickness, the localized resistance distribution would be uniform, so the electron current would not all flow toward the P2 channel, but would instead but have a distribution.

As shown in FIGS. 1-3, for a non-uniform TCO layer 160, the TCO thickness contributes a resistance distribution depending on its thickness. The resistance of a conductor is given by

R=μL/A,

where R is the resistance, ρ is the resistivity (a material property), L is the conductor length, and A is the cross-sectional area of the conductor. Thus, by providing a TCO layer 160 having a thickness that increases from left to right in each solar cell 110, the area A increases from left to right, and the resistance R has a gradient within the TCO layer 160. As the cross sectional area increases from left to right (in proportion to the increase in thickness), the resistance decreases proportionally.

Thus, as shown in FIG. 2, the TCO layer 160 has a thickness gradient, from a minimum thickness Tmin at the left of each solar cell to a thickness T2 above the P2 scribe line. In some embodiments, the TCO layer 160 has a thickness gradient, from a minimum thickness Tmin at the left of each solar cell to a maximum thickness Tmax at the right of each solar cell 110. In some embodiments as shown in FIGS. 1-3, the thickness Tmin is immediately to the right of the P3 scribe line of the adjacent solar cell (i.e., at the left end of each solar cell). The thickness Tmax is immediately to the left of the P3 scribe line (the right end) of each solar cell.

With a thickness gradient, the resistance gradient dominates the current distribution. The thinner TCO layer 160 contribute localized higher resistance. With the thickness gradient, the electron current will tend to flow towards the P2 scribe line (channel) and have a current path with lower-resistance.

Further, by controlling the final resistance through a gradient TCO structure, a higher transmittance can be obtained due to a region having a thinner TCO layer (at the left side of each solar cell 110) and further enhance photocurrent.

By providing a gradient that increases from Tmin to T2 between the left end of the solar cell and the P2 scribe line, a resistance gradient is provided throughout the horizontal path extracting the charge carriers and delivering the charge carriers to the P2 scribe line. Further, by providing a continuous thickness gradient from Tmin at the first end 161 of the solar cell to Tmax at the second end 162 of the solar cell, the complexity of the step of forming the thickness gradient can be reduced in some embodiments.

In some embodiments, the thickness of the front contact layer 160 increases continuously at least from a value of Tmin at the first end 161 to a value of T2 at the P2 scribe line.

In some embodiments, the thickness of the front contact layer 160 increases continuously from a value of Tmin at the first end 161 to a value of Tmax at the second end 162.

In some embodiments, the thickness of the front contact layer 160 increases linearly from a value of Tmin at the first end 161 to a value of Tmax at the second end 162. In other embodiments (not shown), the top surface can have a curved contour (not shown).

In some embodiments, the thickness T2 of the front contact layer 160 at the P2 scribe line is in a range from five to 20 times the thickness Tmin of the front contact layer 160 at the first end 161. For example, in some embodiments, the thickness Tmin is about 100 nanometers (nm) or more, and the thickness T2 is in a range from about 500 nm to about 2000 nm.

Comparing the current flow J in FIG. 2 to the current flow J₀ shown in FIG. 1, with a thickness gradient, the charge carriers have a greater cross sectional area to flow towards, as they move from left to right, towards the P2 scribe line. By selecting the thicknesses Tmin and T2, the current density can be maintained substantially constant from the left side of the TCO layer 160 to the P2 scribe line. In other embodiments, the current density gradient is substantially reduced relative to a TCO layer having a constant thickness.

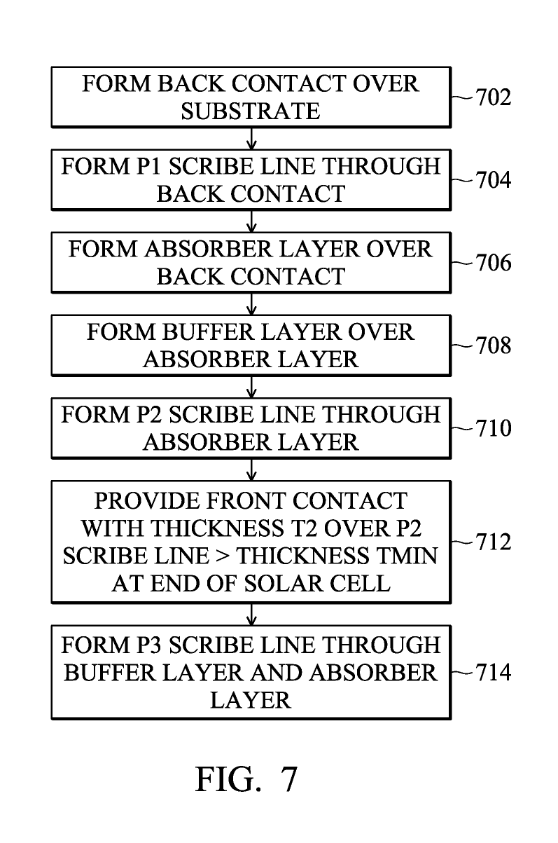

FIG. 7 is a flow chart of a method for forming a solar cell as described above.

At step 702, a back contact layer 130 is formed over a solar cell substrate 120. The back contact can deposited by PVD, for example sputtering, of a metal such as Mo, Cu or Ni over the substrate, or by CVD or ALD or other suitable techniques.

At step 704, the P1 scribe line is scribed though the back contact layer 130. The P1 scribe line can be formed by mechanical scribing, laser, or other suitable scribing process

At step 706, the absorber layer 140 is formed over the back contact layer 130. The absorber layer can be deposited by PVD (e.g., sputtering), CVD, ALD, electro deposition or other suitable techniques. For example, a CIGS absorber layer can be formed by sputtering a metal film comprising copper, indium and gallium then applying a selenization process to the metal film.

At step 708, the buffer layer 150 is formed over the absorber layer. The buffer layer 150 can be deposited by chemical deposition (e.g., chemical bath deposition), PVD, ALD, or other suitable techniques.

At step 710, the P2 scribe line is formed through the buffer layer and absorber layer 140.

At step 712, a front contact layer 160 is formed over the absorber layer 150. The front contact layer has a first end 161 and a second end 162, where the P2 scribe line is closer to the second end 162 than to the first end 161. A thickness T2 of the front contact layer 160 above the P2 scribe line is greater than the thickness Tmin of the front contact layer 160 at the first end 161.

At step 714, the P3 scribe line is formed through the buffer layer 150 and the absorber layer 140.

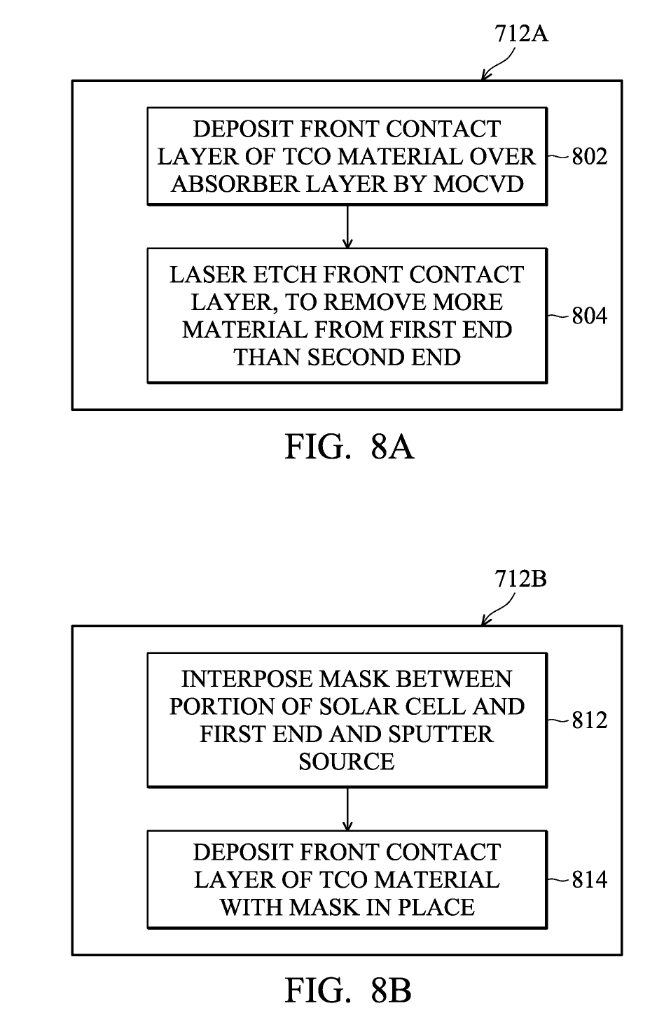

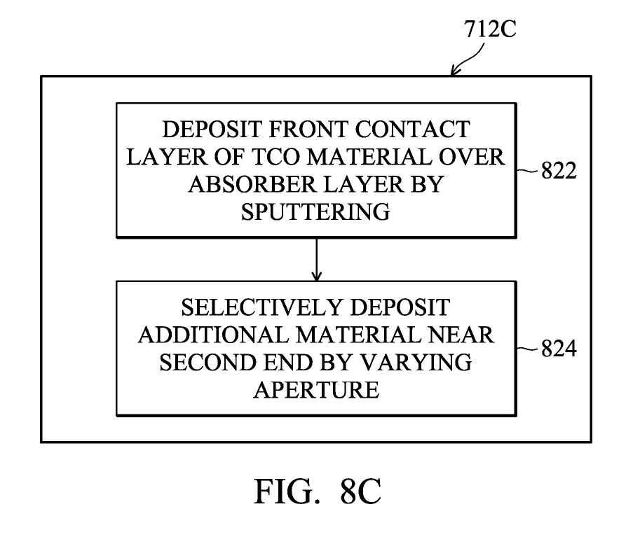

FIGS. 8A-8C show three alternative implementations of step 712 of FIG. 7, according to some embodiments.

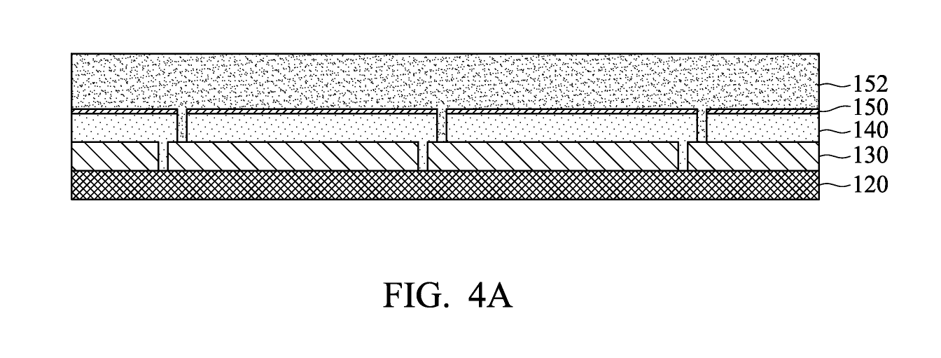

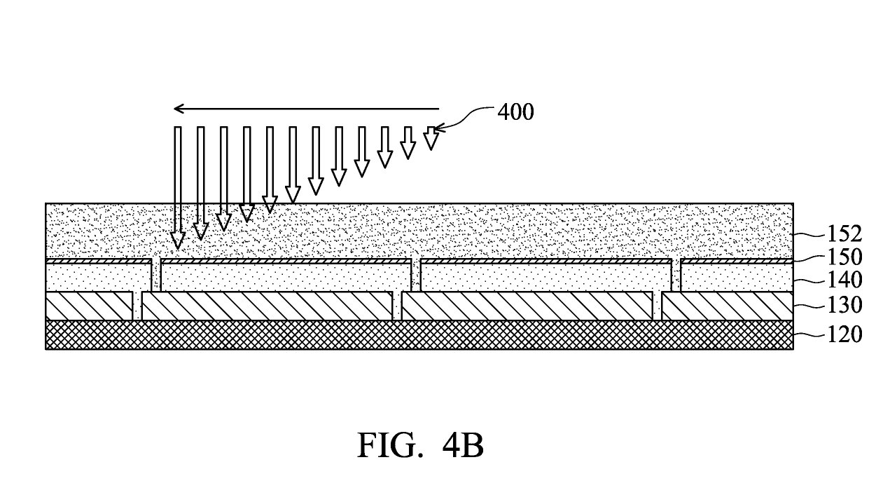

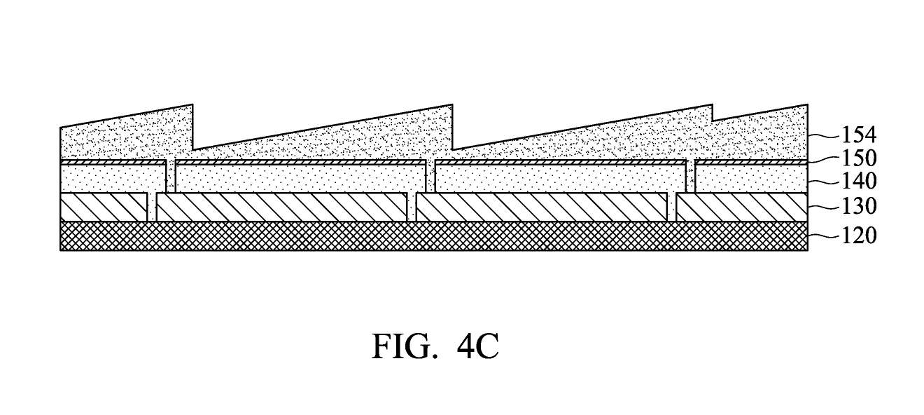

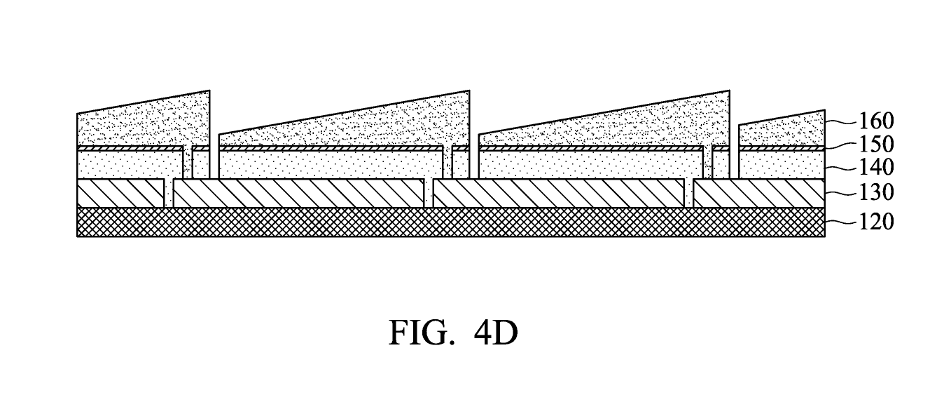

FIG. 8A shows a method according to some embodiments, in which a uniform layer of TCO material is deposited and then selectively etched to form a thickness gradient. FIGS. 4A-4D show four steps in forming the front contact layer 160 having a thickness gradient, according to some embodiments of step 712A of FIG. 8A.

As shown in FIGS. 8A and 4A, in some embodiments, the step 712A of forming the front contact layer 160 comprises a step 802 of depositing a layer 152 of a front contact layer material over the absorber layer 140. In some embodiments, the depositing includes sputtering.

At step 804 of FIG. 8A, the front contact layer material is etched using a laser 400 (FIG. 4B), so as to remove more material from the first end 161 than from the second end 162 of the layer 152 of front contact material. In some embodiments, the laser 400 has a wavelength in a range from about 266 nm about 355 nm, with a pico-second pulse. At the conclusion of this step, the front contact material 154 has a thickness gradient, from a thickness of Tmin at the first end 161 to a thickness of Tmax at the second end 162, with a thickness T2 above the P2 scribe line, as shown in FIG. 4C.

The P3 scribe line is formed through the front contact 160, the buffer layer 150 and the absorber layer 140. The resulting structure is shown in FIG. 4D.

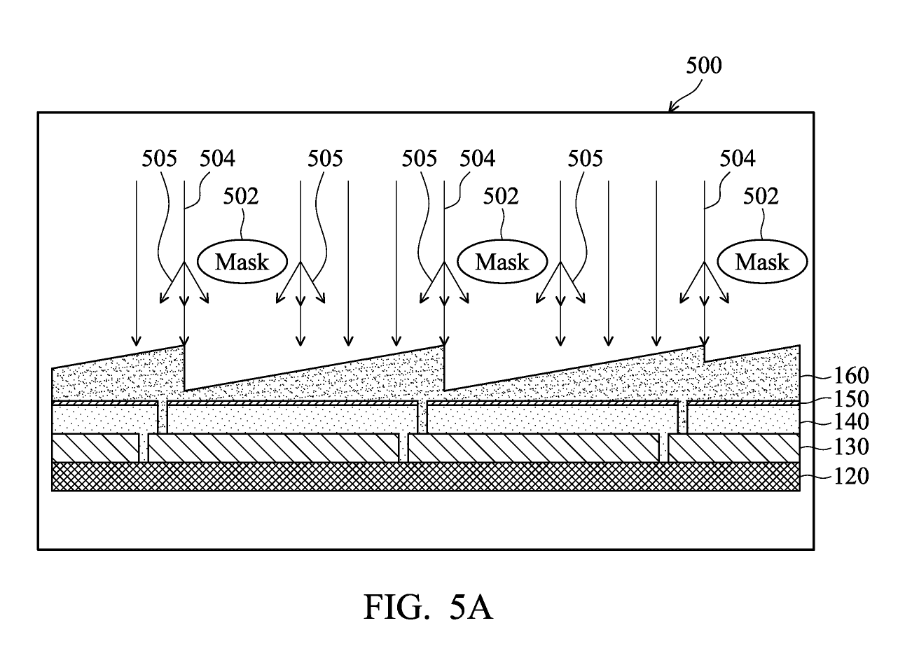

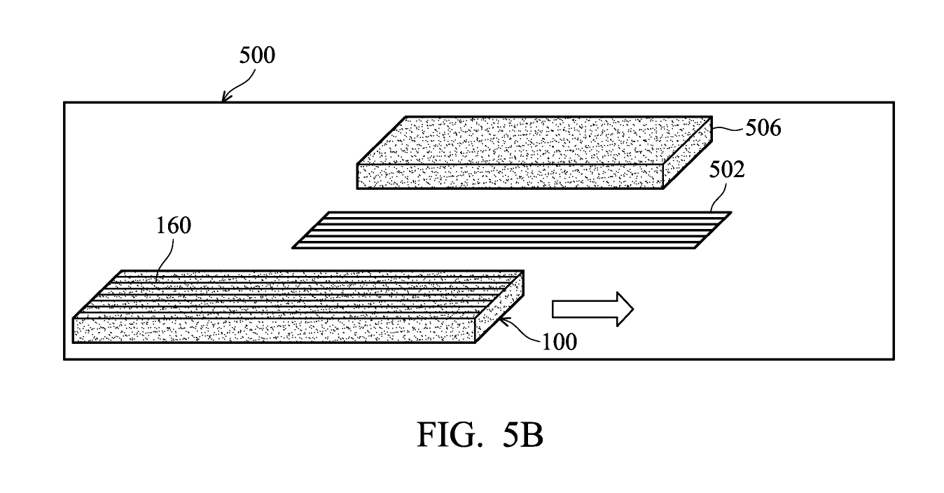

In other embodiments, an additive method is used to form the thickness gradient. Thus, TCO material can be deposited with a non-uniform thickness. FIGS. 8B, 5A and 5B show a first alternative method 712B for performing step 712 of FIG. 7, according to some embodiments.

In step 812, a mask 502 is interposed between a sputter source (e.g., sputter target 506) and the substrate 100.

At step 814, the TCO material is selectively deposited with the mask interposed between a portion of the solar cell near the first end 161 and a sputter source. In some embodiments, the step of forming the front contact layer comprises selectively depositing more front contact layer material near the second end than is deposited at the first end.

When the plasma (marked as arrows 504) reach the mask 502, the ions are retarded and scattered in the direction of arrows 505. Accordingly, the thicker region of the front contact layer 160 (near the second end 162 of the solar cell 100) is attributed to the overlap of directly flowing plasma 504 and the scattered ions 505. The thinner region (near the first end 161 of the solar cell 100) is due only to the scattered ions 505.

In other embodiments, the deposition can be performed in two steps, including: a first step of depositing a uniform layer of a front contact layer material over the absorber layer without the mask in place; and a second step of selectively depositing additional front contact layer material near the second end 162, while the mask 502 is in place.

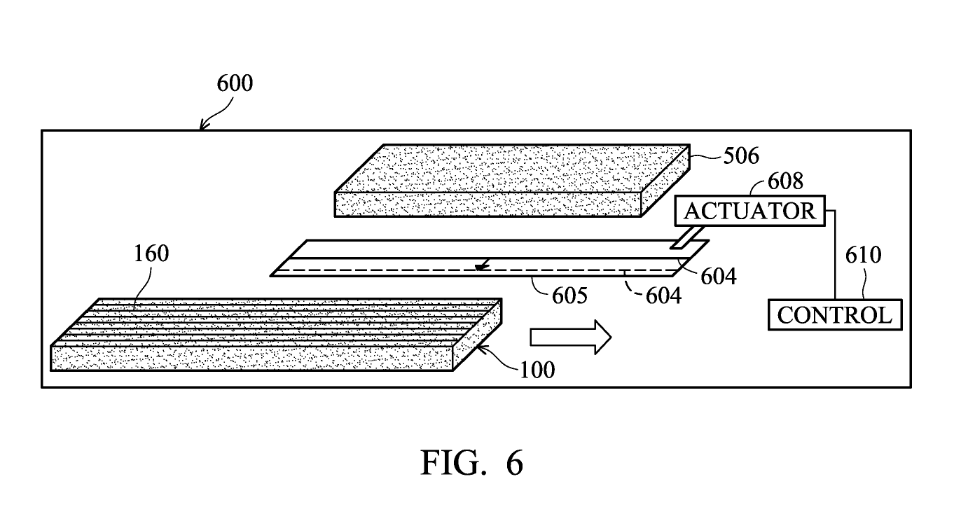

FIGS. 8C and 6 show another embodiment of a method of performing step 712. In step 712C of FIG. 8C, the selectively depositing comprises varying an aperture of a sputter source while depositing the front contact layer material.

FIG. 6 is a schematic diagram showing a chamber 600 having a sputter source (e.g., sputter target 506) and an aperture 605 defined by one or more movable plates 604. The plate(s) 604 can be moved from a retracted position, in which the aperture 605 is larger, and an extended position (shown in phantom) in which the aperture 605 is smaller. In some embodiments, the plate(s) 604 can be moved continuously by an actuator 608 under control of a controller 610, which can be a programmable logic controller, microcomputer, embedded microprocessor or microcontroller, or other processing device. By controlling the position of the plate(s) 604, a continuous thickness profile can be achieved.

Some embodiments described herein have a front contact layer which increases in thickness linearly. In other embodiments (not shown), the thickness of the front contact increases quadratically, so that the thickness changes more rapidly closer to one end (the first end or second end) than at the other end (the second or first end, respectively). In still other embodiments, the thickness of the front contact layer increases discretely in a stepwise fashion.

Thus, a solar cell as described herein enhances photocurrent by providing a thickness gradient in the front contact layer. By providing a thicker front contact layer over the P2 scribe line and a thinner front contact layer at the end of the solar cell distal from the P2 scribe line, high average light transmittance is achieved, while selectively reducing TCO resistance near the P2 scribe line, to improve series resistance.

In some embodiments, a solar cell comprises a back contact layer over a substrate; an absorber layer over the back contact layer, having a scribe line extending therethrough; and a front contact layer over the absorber layer. The front contact layer has a first end and a second end opposite the first end, wherein the scribe line is closer to the second end than to the first end, and the front contact layer has a thickness above the scribe line that is greater than the thickness of the front contact layer at the first end.

In some embodiments, a solar cell comprises a back contact layer over a substrate; an absorber layer over the back contact layer, having a P2 scribe line extending therethrough; and a front contact layer over the absorber layer. The solar cell has a first P3 scribe line at a first end and a second P3 scribe line at a second end opposite the first end. Each P3 scribe line extends through the front contact layer and the absorber layer. The P2 scribe line is closer to the second end than to the first end, and the front contact layer has a thickness above the P2 scribe line that is greater than the thickness of the front contact layer at the first end.

In some embodiments, a method comprises: forming a back contact layer over a solar cell substrate; forming an absorber layer over the back contact layer; forming a scribe line through the absorber layer; and forming a front contact layer over the absorber layer. The front contact layer has a first end and a second end, wherein the scribe line is closer to the second end than to the first end, and a thickness of the front contact layer above the scribe line is greater than the thickness of the front contact layer at the first end.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell comprising:
a back contact layer over a substrate;
an absorber layer over the back contact layer, having a scribe line extending therethrough; and
a front contact layer over the absorber layer, the front contact layer having a first end and a second end opposite the first end, wherein the scribe line is closer to the second end than to the first end, and the front contact layer has a thickness above the scribe line that is greater than the thickness of the front contact layer at the first end.

2. The solar cell of claim 1, wherein the thickness of the front contact layer increases continuously at least from the first end to the scribe line.

3. The solar cell of claim 1, wherein the thickness of the front contact layer increases continuously from the first end to the second end.

4. The solar cell of claim 1, wherein the thickness of the front contact layer increases linearly between the first end and the second end.

5. The solar cell of claim 1, wherein the thickness of the front contact layer at the scribe line is in a range from five to 20 times the thickness of the front contact layer at the first end.

6. The solar cell of claim 1, wherein the front contact layer comprises a transparent conductive oxide material.

7. The solar cell of claim 1, wherein the scribe line is a P2 scribe line, and the solar cell further comprises a first P3 scribe line at the first end, the P3 scribe line extending through the front contact layer and the absorber layer, and wherein the thickness of the front contact layer increases linearly from the first P3 scribe line to the P2 scribe line.

8. The solar cell of claim 7, wherein the solar cell has a second P3 scribe line at the second end, and the thickness of the front contact layer increases linearly from the first P3 scribe line to the second P3 scribe line.

9. A solar cell comprising:
a back contact layer over a substrate;
an absorber layer over the back contact layer, having a P2 scribe line extending therethrough; and
a front contact layer over the absorber layer, the solar cell having a first P3 scribe line at a first end and a second P3 scribe line at a second end opposite the first end, each P3 scribe line extending through the front contact layer and the absorber layer, wherein the P2 scribe line is closer to the second end than to the first end, and the front contact layer has a thickness above the P2 scribe line that is greater than the thickness of the front contact layer at the first end.

10. The solar cell of claim 9, wherein the thickness of the front contact layer increases continuously at least from the first end to the P2 scribe line.

11. The solar cell of claim 9, wherein the thickness of the front contact layer increases continuously from the first end to the second end.

12. The solar cell of claim 9, wherein the thickness of the front contact layer increases linearly between the first end and the second end.

13. The solar cell of claim 9, wherein the thickness of the front contact layer at the P2 scribe line is in a range from five to 20 times the thickness of the front contact layer at the first end.

14. A method, comprising:
forming a back contact layer over a solar cell substrate;
forming an absorber layer over the back contact layer;
forming a scribe line through the absorber layer;
forming a front contact layer over the absorber layer, the front contact layer having a first end and a second end, wherein the scribe line is closer to the second end than to the first end, and a thickness of the front contact layer above the scribe line is greater than the thickness of the front contact layer at the first end.

15. The method of claim 14, wherein the step of forming the front contact layer comprises:
depositing a layer of a front contact layer material over the absorber layer; and
etching the front contact layer material, so as to remove more material from the first end than from the second end.

16. The method of claim 15, wherein the etching comprises using a laser.

17. The method of claim 16, wherein the depositing includes performing metal organic chemical vapor deposition.

18. The method of claim 14, wherein the step of forming the front contact layer comprises:
selectively depositing more front contact layer material near the second end than is deposited at the first end.

19. The method of claim 18, wherein the selectively depositing comprises varying an aperture of a sputter source while depositing the front contact layer material.

20. The method of claim 18, wherein the selectively depositing includes depositing material with a mask interposed between a portion of the solar cell near the first end and a sputter source.
